(19) United States
(12) Patent Application Publication
(10) Pub. No.: US 2025/0380460 A1
(43) Pub. Date: Dec. 11, 2025

(54) THIN FILM TRANSISTOR, DISPLAY APPARATUS INCLUDING SAME, AND MANUFACTURING METHOD OF THIN FILM TRANSISTOR

(71) Applicants: SAMSUNG DISPLAY CO., LTD., Yongin-si (KR); Industry-University Cooperation Foundation Hanyang University ERICA Campus, Ansan-si (KR)

(72) Inventors: Joonseok Park, Yongin-si (KR); Suhyun Kim, Seongnam-si (KR); Saeroonter Oh, Seoul (KR); Hyoungdo Kim, Yongin-si (KR); Jaehyeong Park, Gwacheon-si (KR); Sunhee Lee, Yongin-si (KR)

(21) Appl. No.: 19/217,053

(22) Filed: May 23, 2025

(30) Foreign Application Priority Data
May 24, 2024 (KR) 10-2024-0068025

(51) Int. Cl. H10D 30/67; H10K 59/124

(52) U.S. Cl. CPC H10D 30/6736; H10D 30/6755; H10K 59/124

(57) ABSTRACT

A thin film transistor includes a substrate. A first electrode is disposed on the substrate. The first electrode has a first opening defined therein. A first insulating layer is disposed on the first electrode. The first insulating layer has a second opening defined therein. The second opening overlaps the first opening. A second electrode is disposed on the first insulating layer and has a third opening defined therein. The third opening overlaps the first opening. A semiconductor layer is disposed on the second electrode and overlaps the first opening, the second opening, and the third opening. A second insulating layer is disposed on the semiconductor layer. A gate electrode is disposed on the second insulating layer.

### CROSS-REFERENCE TO RELATED APPLICATION

This application claims priority under 35 U.S.C. § 119 to Korean Patent Application No. 10-2024-0068025, filed on May 24, 2024 in the Korean Intellectual Property Office, the disclosure of which is incorporated by reference in its entirety herein.

### 1. TECHNICAL FIELD

One or more embodiments of the present disclosure relate to a thin film transistor, a display apparatus including the same, and a method of manufacturing the thin film transistor.

### 2. DISCUSSION OF RELATED ART

Display apparatuses have become increasingly thin and lightweight, and the uses thereof have become more diversified along with the advancement of the information society. Display apparatuses may include a plurality of pixels. Each of the pixels may include a light-emitting diode and a pixel circuit for controlling the brightness of the light-emitting diode. The pixel circuit may include thin film transistors connected to wirings, such as data lines, gate lines and voltage lines, as well as capacitors.

As the resolution of display apparatuses has increased, various forms of thin film transistors have been designed to increase the degree of integration of the pixel circuits.

### SUMMARY

As thin film transistors are gradually miniaturized, a parasitic capacitance between a gate electrode and a source-drain electrode may be increased, resulting in a decrease of an on-current of the thin film transistor. One or more embodiments include a thin film transistor with a reduced parasitic capacitance between a gate electrode and a source-drain electrode, a display apparatus including the thin film transistor, and a method of manufacturing a thin film transistor. However, the one or more embodiments are only examples, and the scope of the disclosure is not limited thereto.

Additional aspects will be set forth in part in the description which follows and, in part, will be apparent from the description, or may be learned by practice of the described embodiments of the present disclosure.

According to an embodiment of the present disclosure, a thin film transistor includes a substrate. A first electrode is disposed on the substrate. The first electrode has a first opening defined therein. A first insulating layer is disposed on the first electrode. The first insulating layer has a second opening defined therein. The second opening overlaps the first opening. A second electrode is disposed on the first insulating layer and has a third opening defined therein. The third opening overlaps the first opening. A semiconductor layer is disposed on the second electrode and overlaps the first opening, the second opening, and the third opening. A second insulating layer is disposed on the semiconductor layer. A gate electrode is disposed on the second insulating layer.

In an embodiment, the semiconductor layer may cover the inner sides of each of the first opening, the second opening, and the third opening.

In an embodiment, the first opening, the second opening, and the third opening may have a circular shape in a plan view.

In an embodiment, the semiconductor layer may have a circular shape in a plan view.

In an embodiment, a width of the gate electrode in a first direction may be greater than or equal to a diameter of the first opening in the first direction.

In an embodiment, a groove is defined on an upper surface of the second insulating layer and the gate electrode may fill the groove.

In an embodiment, a taper angle of an inner side of the second opening may be less than or equal to 90°.

In an embodiment, a taper angle of the inner side of the first opening may be a first angle, the taper angle of the inner side of the second opening may be a second angle, a taper angle of the inner side of the third opening may be a third angle, and the first angle and the third angle may be less than the second angle.

In an embodiment, the thin film transistor may further include an etch stopper arranged between the substrate and the first electrode. A bottom surface of the first opening may expose an upper surface of the etch stopper.

In an embodiment, the semiconductor layer may include an oxide semiconductor material.

According to an embodiment of the present disclosure, a display apparatus includes a substrate. A thin film transistor is disposed on the substrate. A light-emitting diode electrically connects to the thin film transistor. The thin film transistor includes a first electrode disposed on the substrate. The first electrode has a first opening defined therein. A first insulating layer is disposed on the first electrode. The first insulating layer has a second opening defined therein. The second opening overlaps the first opening. A second electrode is disposed on the first insulating layer. The second electrode has a third opening defined therein. The third opening overlaps the first opening. A semiconductor layer is disposed on the second electrode and overlaps the first opening, the second opening, and the third opening. A second insulating layer is disposed on the semiconductor layer. A gate electrode is disposed on the second insulating layer.

According to an embodiment of the present disclosure, a method of manufacturing a thin film transistor includes forming a first electrode on a substrate, forming a first insulating layer on the first electrode, forming a second electrode on the first insulating layer, forming an opening penetrating through the second electrode, the first insulating layer, and the first electrode, forming a semiconductor layer on the second electrode to overlap the opening, forming a second insulating layer on the semiconductor layer, and forming a gate electrode on the second insulating layer.

In an embodiment, the semiconductor layer may cover an inner side of the opening.

In an embodiment, the opening may have a circular shape in a plan view.

In an embodiment, a width of the gate electrode in a first direction may be greater than or equal to a diameter of a bottom surface of the opening in the first direction.

In an embodiment, a groove is defined on an upper surface of the second insulating layer, and the gate electrode may fill the groove.

In an embodiment, the opening may have a first opening defined in the first electrode, a second opening defined in the first insulating layer, and a third opening defined in the second electrode. The first opening, the second opening, and the third opening overlap each other. A taper angle of an inner side of the second opening may be less than or equal to 90°.

In an embodiment, a taper angle of the inner side of the first opening may be a first angle, the taper angle of the inner side of the second opening may be a second angle, a taper angle of the inner side of the third opening may be a third angle, and the first angle and the third angle may be less than the second angle.

In an embodiment, the method of manufacturing the thin film transistor may further include forming an etch stopper on the substrate before the forming of the first electrode.

In an embodiment, the opening may expose an upper surface of the etch stopper.

According to an embodiment of the present disclosure, a thin film transistor includes a substrate. A first electrode is disposed on the substrate. A first insulating layer is disposed on the first electrode. A second electrode is disposed on the first insulating layer. An opening penetrates through the first electrode, the first insulating layer and the second electrode. A semiconductor layer is disposed in the opening and directly contacts sides of the first electrode, the first insulating layer and the second electrode exposed by the opening. A gate electrode is disposed on the semiconductor layer in the opening. The semiconductor layer disposed in the opening extends vertically between the first electrode and the second electrode and is as a channel area of the thin film transistor.

In an embodiment, inside the opening, the gate electrode does not overlap the first electrode.

In an embodiment, a width of the gate electrode in a first direction is greater than or equal to a diameter of the opening in the first direction. The gate electrode covers an entirety of an inner side of the opening.

In an embodiment, the opening exposes an upper surface of the substrate.

In an embodiment, an etch stopper is disposed between the substrate and the first electrode. The opening exposes an upper surface of the etch stopper.

Other aspects, features, and advantages may become clear from the following drawings, the claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment of the present disclosure;

FIGS. 2A and 2B are circuit diagrams schematically illustrating a pixel according to embodiments of the present disclosure;

FIG. 3 is a schematic cross-sectional view of an organic light-emitting diode according to an embodiment of the present disclosure;

FIG. 4 is a schematic plan view of a thin film transistor according to an embodiment of the present disclosure;

FIG. 5 is a schematic cross-sectional view of the thin film transistor of FIG. 4 taken along line A-A′ according to an embodiment of the present disclosure;

FIGS. 6A to 6E are cross-sectional views schematically illustrating some steps of a method of manufacturing a thin film transistor, according to embodiments of the present disclosure;

FIGS. 7A to 7D are cross-sectional views schematically illustrating some steps of a method of manufacturing a thin film transistor, according to embodiments of the present disclosure;

FIG. 8A is a schematic cross-sectional view of a thin film transistor according to an embodiment of the present disclosure;

FIG. 8B is a schematic cross-sectional view of the thin film transistor of FIG. 8A taken along line B-B′ according to an embodiment of the present disclosure;

FIG. 9 is a schematic cross-sectional view of a thin film transistor according to an embodiment of the present disclosure;

FIG. 10A is a graph showing a parasitic capacitance between a gate electrode and a first electrode of a thin film transistor of a comparative example and FIG. 10B is a graph showing a parasitic capacitance between a gate electrode and a first electrode of a thin film transistor according to an embodiment of the present disclosure; and

FIG. 11A is a graph showing an on-current of the thin film transistor of the comparative example and FIG. 11B is a graph showing an on-current of a thin film transistor according to an embodiment of the present disclosure.

### DETAILED DESCRIPTION OF EMBODIMENTS

Reference will now be made in detail to embodiments, examples of which are illustrated in the accompanying drawings, wherein like reference numerals refer to like elements throughout. In this regard, embodiments of the present disclosure may have different forms and should not be construed as being limited to the descriptions set forth herein. Accordingly, embodiments are merely described below, by referring to the figures, to explain aspects of the present disclosure. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

Since the present disclosure may have diverse modified embodiments, non-limiting embodiments are illustrated in the drawings and are described in the detailed description. An effect and a characteristic of embodiments of the present disclosure, and a method of accomplishing these will be apparent when referring to the described embodiments with reference to the drawings. However, the present disclosure may be embodied in many different forms and should not be construed as limited to the described embodiments set forth herein.

One or more non-limiting embodiments of the present disclosure will be described below in more detail with reference to the accompanying drawings. Those elements that are the same or are in correspondence are rendered the same reference numeral regardless of the figure number, and redundant descriptions thereof may be omitted for economy of description.

In the specification, the terms “first” and “second” are not used in a limited sense and are used to distinguish one component from another component.

In the specification, an expression used in the singular encompasses the expression of the plural, unless it has a clearly different meaning in the context.

In the specification, it will be further understood that the terms “comprise” and/or “comprising” used herein specify the presence of stated features or components, but do not preclude the presence or addition of one or more other features or components.

It will be understood that when a layer, region, or element is referred to as being “formed on” another layer, area, or element, it can be directly or indirectly formed on the other layer, region, or element. That is, for example, intervening layers, regions, or elements may be present. When a layer, region, or element is referred to as being “formed directly on” another layer, region, or element, no intervening layers, regions, or elements may be present.

When a layer, region, component, or the like is connected to another layer, region, component, or the like, the layer, the region, the component, or the like may be directly connected thereto and/or may be indirectly connected thereto with an intervening layer, region, component, or the like therebetween. For example, in the specification, when a layer, region, component, or the like is electrically connected to another layer, region, component, or the like, the layer, region, component, or the like may be directly electrically connected thereto and/or may be indirectly electrically connected thereto with an intervening layer, region, component, or the like therebetween.

Herein, the x direction, the y direction, and the z direction are not necessarily limited to directions along three axes of the rectangular coordinate system, and may be interpreted in a broader sense. For example, the x direction, the y direction, and the z direction may be perpendicular to one another, or may represent different directions that are not perpendicular to one another.

Herein, a “planar view” refers to viewing the corresponding portion from above (for example, viewing from a direction perpendicular to an upper surface of a substrate), and “a cross-sectional view” refers to viewing, from the side, a cross section of the corresponding portion cut vertically.

Herein, a first element “overlapping” a second element refers to the first element being disposed over or below the second element, resulting in an overlapping of at least a portion in a plan view.

When a certain embodiment may be implemented differently, a specific process order may be performed differently from the described order. For example, two consecutively described processes may be performed substantially at the same time or performed in an order opposite to the described order.

In the drawings, for convenience of description, sizes of components may be exaggerated or reduced. For example, since sizes and thicknesses of elements in the drawings may be arbitrarily illustrated for convenience of description, embodiments of the present disclosure are not necessarily limited thereto.

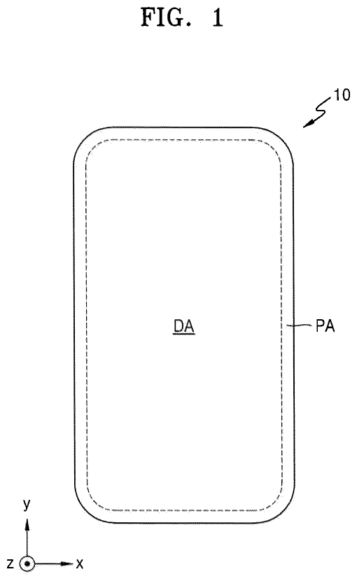

FIG. 1 is a schematic plan view of a display apparatus according to an embodiment.

Referring to FIG. 1, the display apparatus 10 may include a display area DA for displaying an image and a peripheral area PA outside the display area DA (e.g., in a plan view). The display apparatus 10 may provide a certain image by using light emitted from a plurality of pixels arranged in the display area DA. In an embodiment, in a plan view, the display area DA may be rectangular. However, embodiments of the present disclosure are not necessarily limited thereto. For example, in some embodiments, the display area DA may have a polygonal shape, a circular shape, an elliptical shape, or an atypical shape. A corner of the display area DA may be round.

In an embodiment, the display apparatus 10 may include a display area DA that is shorter in the first direction (e.g., the x direction) than in the second direction (e.g., the y direction). In some embodiments, the display apparatus 10 may include a display area DA that is longer in the first direction (e.g., the x direction) than in the second direction (e.g., the y direction).

The peripheral area PA may be arranged outside of the display area DA, and may surround at least a portion of the display area DA (e.g., in a plan view). In an embodiment, the peripheral area PA may be a kind of non-display area in which pixels are not arranged. The peripheral area PA may include pads to which various wires, circuits, and printed circuit boards or driver IC chips configured to transmit electrical signals to the display area DA may be attached.

The display apparatus 10 according to an embodiment displays at least one video and/or still image and may be used as a display screen of portable electronic devices such as mobile phones, smart phones, tablet personal computers (PC), mobile communication terminals, electronic note function devices, electronic books, portable multimedia players (PMP), navigation devices, and an ultra mobile PCs (UMPC), as well as various products such as televisions, laptop computers, monitors, billboards, and internet of things (IoT) devices. However, embodiments of the present disclosure are not necessarily limited thereto. In addition, the display apparatus 10 according to an embodiment may be used for wearable devices such as a smart watch, a watch phone, a glasses-type display, and a head mounted display (HMD). In addition, the display apparatus 10 according to an embodiment may be used in a vehicle dashboard, a center information display (CID) arranged in a center fascia or dashboard of a vehicle, a room mirror display replacing a side mirror of a vehicle, and a display for entertainment in the back seat of a vehicle, the display being arranged in the rear surface of a front seat.

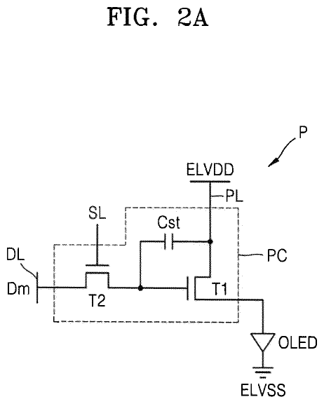

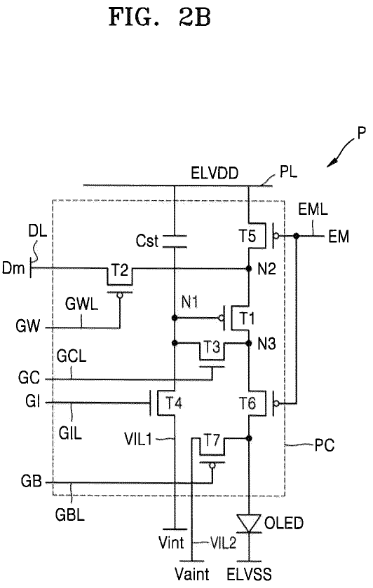

FIGS. 2A and 2B are equivalent circuit diagrams schematically illustrating a pixel according to embodiments of the present disclosure.

Referring to FIG. 2A, the pixel P may include a pixel circuit PC and a display element electrically connected to the pixel circuit PC. In an embodiment, the display element may be an organic light-emitting diode OLED.

In an embodiment, the pixel circuit PC may include a first transistor T1, a second transistor T2, and a storage capacitor Cst. In an embodiment, the second transistor T2 may be a switching transistor that is connected to (e.g., electrically connected thereto) a scan line SL and a data line DL, and may be configured to transmit a data signal Dm input from a data line DL to the first transistor T1, according to a gate signal input from a scan line SL. The storage capacitor Cst may be connected to (e.g., electrically connected thereto) the second transistor T2 and a driving voltage line PL and may be configured to store a voltage corresponding to a difference between the data signal Dm received from the second transistor T2 and a driving voltage ELVDD supplied to a driving voltage line PL.

In an embodiment, the first transistor T1 may be a driving transistor that is connected to the driving voltage line PL and the storage capacitor Cst and may be configured to control a driving current flowing from the driving voltage line PL through the organic light-emitting diode OLED, according to a value of the voltage stored in the storage capacitor Cst. The organic light-emitting diode OLED may emit light having a certain brightness according to the driving current. A pixel electrode (e.g., an anode) of the organic light-emitting diode OLED may be electrically connected to the first transistor T1 and an opposite electrode (e.g., a cathode) may be provided with a common voltage ELVSS.

Referring to FIG. 2B, in an embodiment the pixel circuit PC may include seven transistors and one capacitor. The pixel circuit PC may include first to seventh transistors T1, T2, T3, T4, T5, T6, and T7 and the storage capacitor Cst. In some embodiments, the pixel circuit PC may further include a boost capacitor.

In an embodiment, the first transistor T1 may be a driving transistor configured to output a driving current corresponding to the data signal Dm, and each of the second to seventh transistors T2 to T7 may be a switching transistor configured to transmit signals.

The first terminal (e.g., a first electrode) of each of the first to seventh transistors T1 to T7 may be a source or a drain and a second terminal (e.g., a second electrode) may be a different terminal from the first terminal. For example, in an embodiment in which the first terminal is a drain, the second terminal may be a source.

The first to seventh transistors T1, T2, T3, T4, T5, T6, and T7 may be connected to (e.g., electrically connected thereto) the signal line. In an embodiment, the signal line may include a first gate line GWL configured to transmit a first gate signal GW, a second gate line GCL configured to transmit a second gate signal GC, a third gate line GIL configured to transmit a third gate signal GI, a fourth gate line GBL configured to transmit a fourth gate signal GB, an emission control line EML configured to transmit an emission control signal EM, and the data line DL configured to transmit the data signal Dm. The pixel circuit PC may be electrically connected to a voltage line, such as the driving voltage line PL, a first initialization voltage line VIL1, and a second initialization voltage line VIL2. The driving voltage line PL may be configured to transmit the driving voltage ELVDD to the first transistor T1 via the fifth transistor T5, and the first initialization voltage line VIL1 and the second initialization voltage line VIL2 may each be configured to transmit initialization voltages Vint and Vaint (hereinafter, also referred to as a first initialization voltage Vint and a second initialization voltage Vaint) initializing the gate electrode of the first transistor T1 and the pixel electrode (e.g., the anode) of the organic light-emitting diode OLED.

The first transistor T1 may be a driving transistor. The gate of the first transistor T1 may be connected to a first node N1, the first terminal of the first transistor T1 may be connected to a second node N2, and the second terminal of the first transistor T1 may be connected to a third node N3. In an embodiment, the first transistor T1 may supply the driving current to the organic light-emitting diode OLED according to a switching operation of the second transistor T2.

The second transistor T2 may be a data write transistor. The gate of the second transistor T2 may be connected to the first gate line GWL, the first terminal of the second transistor T2 may be connected to the data line DL, and the second terminal of the second transistor T2 may be connected to the second node N2. In an embodiment, the second transistor T2 may be turned on according to the first gate signal GW received through the first gate line GWL and may perform a switching operation for transmitting the data signal Dm transmitted through the data line DL to the first terminal of the first transistor T1.

The third transistor T3 may be a compensation transistor that compensates for a threshold voltage of the first transistor T1. The gate of the third transistor T3 may be connected to the second gate line GCL, the first terminal of the third transistor T3 may be connected to the first node N1, and the second terminal of the third transistor T3 may be connected to the third node N3. In an embodiment, the third transistor T3 may be turned on according to the second gate signal GC received through the second gate line GCL and may electrically connect the gate of the first transistor T1 to the second terminal (e.g., the drain) of the first transistor T1, thereby diode-connecting the first transistor T1.

The fourth transistor T4 may be a first initialization transistor configured to initialize the first node N1. The gate of the fourth transistor T4 may be connected to the third gate line GIL, the first terminal of the fourth transistor T4 may be connected to the first initialization voltage line VIL1, and the second terminal of the fourth transistor T4 may be connected to the first node N1. In an embodiment, the fourth transistor T4 may be turned on according to the third gate signal GI received through the third gate line GIL and may perform an initializing operation of initializing a voltage of the gate of the first transistor T1 by transmitting the first initialization voltage Vint to the first node N1.

The fifth transistor T5 may be an operation control transistor. The gate of the fifth transistor T5 may be connected to the emission control line EML, the first terminal of the fifth transistor T5 may be connected to the driving voltage line PL, and the second terminal of the fifth transistor T5 may be connected to the second node N2.

The sixth transistor T6 may be an emission control transistor. The gate of the sixth transistor T6 may be connected to the emission control line EML, the first terminal of the sixth transistor T6 may be connected to the third node N3, and the second terminal of the sixth transistor T6 may be connected to the pixel electrode of the organic light-emitting diode OLED.

In an embodiment, the fifth transistor T5 and the sixth transistor T6 may be turned on at the same time according to the emission control signal EM received through the emission control line EML, thereby allowing the driving current to flow through the organic light-emitting diode OLED.

The seventh transistor T7 may be a second initialization transistor initializing the pixel electrode (e.g., the anode) of the organic light-emitting diode OLED. The gate of the seventh transistor T7 may be connected to the fourth gate line GBL, the first terminal of the seventh transistor T7 may be connected to the second initialization voltage line VIL2, and the second terminal of the seventh transistor T7 may be connected to the second terminal of the sixth transistor T6 and the pixel electrode of the organic light-emitting diode OLED. In an embodiment, the seventh transistor T7 may be turned on according to the fourth gate signal GB received through the fourth gate line GBL and initialize the pixel electrode of the organic light-emitting diode OLED by transmitting the second initialization voltage Vaint to the pixel electrode of the organic light-emitting diode OLED.

A first capacitor electrode of the storage capacitor Cst may be connected to the first node N1 and a second capacitor electrode of the storage capacitor Cst may be connected to the driving voltage line PL. The storage capacitor Cst may store charges corresponding to a difference between a voltage of the first node N1 and the driving voltage ELVDD.

The pixel electrode (e.g., the anode) of the organic light-emitting diode OLED may be electrically connected to the first transistor T1 via the sixth transistor T6 and the opposite electrode (e.g., the cathode) may be supplied with the common voltage ELVSS.

Some of the first to seventh transistors T1, T2, T3, T4, T5, T6, and T7 may be N-channel transistors and the others may be P-channel transistors. In an embodiment, as shown in FIG. 2B, the third and fourth transistors T3 and T4 may be N-channel transistors and the others may be P-channel transistors. For example, the third and fourth transistors T3 and T4 may be N-channel transistors including oxide-based semiconductor materials and the others may be a P-channel transistors including silicon-based semiconductor materials.

In an embodiment, the first transistor T1 directly affecting the brightness of the pixel P may include a semiconductor layer including polycrystalline silicon. The third and fourth transistors T3 and T4 connected to the first transistor T1 may include an oxide-based semiconductor layer having a high carrier mobility and a low leakage current, thereby reducing power consumption of the display apparatus and displaying a high-quality image. In some embodiments, the transistors included in the pixel circuit PC may be N-channel transistors.

FIG. 2A illustrates that the pixel circuit PC includes two transistors and one storage capacitor Cst and FIG. 2B illustrates that the pixel circuit PC includes seven transistors and one storage capacitor Cst. However, embodiments of the present disclosure are not necessarily limited thereto. For example, the number of transistors or the number of capacitors may be variously modified according to the design of the pixel circuit PC.

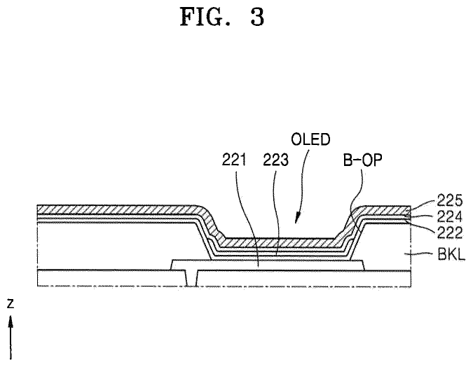

FIG. 3 is a schematic cross-sectional view of the organic light-emitting diode according to an embodiment.

Referring to FIG. 3, the display element according to an embodiment may be the organic light-emitting diode OLED including an organic material. In an embodiment, the organic light-emitting diode OLED may include a pixel electrode 221 arranged on an insulating layer, an opposite electrode 225 facing the pixel electrode 221, and an emission layer 223 between the pixel electrode 221 and the opposite electrode 225 (e.g., in the z direction). In an embodiment, a first functional layer 222 may be arranged between the pixel electrode 221 and the emission layer 223 (e.g., in the z direction) and a second functional layer 224 may be arranged between the emission layer 223 and the opposite electrode 225 (e.g., in the z direction).

In an embodiment, an edge of the pixel electrode 221 may be covered with a bank layer BKL including an insulating material. The bank layer BKL may include a pixel opening B-OP overlapping a center of the pixel electrode 221.

In an embodiment, the pixel electrode 221 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In some embodiments, the pixel electrode 221 may include a reflective layer including silver (Ag), magnesium (Mg), aluminum (AI), platinum (Pt), palladium (Pd), gold (Au), nickel (Ni), neodymium (Nd), iridium (Ir), chromium (Cr), or a compound thereof. In some embodiments, the pixel electrode 221 may further include a layer including ITO, IZO, ZnO, AZO, or In₂O₃ above/below the reflective layer described above.

In an embodiment, the emission layer 223 may include a high molecular-weight or low molecular-weight organic material emitting a predetermined color of light. The first functional layer 222 may include a hole transport layer and/or a hole injection layer. The second functional layer 224 may include an electron transport layer and/or an electron injection layer.

The opposite electrode 225 may include a conductive material having a low work function. For example, in an embodiment the opposite electrode 225 may include a transparent (or transflective) layer including Ag, Mg, Al, Pt, Pd, Au, Ni, Nd, Ir, Cr, Li, Ca, or an alloy thereof. Alternatively, the opposite electrode 225 may further include a layer, such as ITO, IZO, ZnO, AZO, or In₂O₃, on the transparent (or transflective) layer including the material described above.

The display element according to an embodiment of the present disclosure may be a micro scale or nano scale. For example, the display element may be a micro light-emitting diode or a nanorod light-emitting diode. The display element may not necessarily be limited to the organic light-emitting diode OLED and the emission layer of the display element may include an organic material, an inorganic material, a quantum dot, an organic material and a quantum dot, or an inorganic material and a quantum dot.

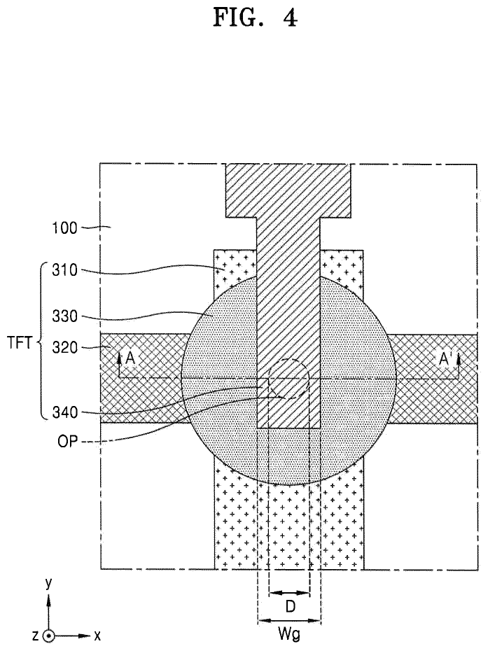

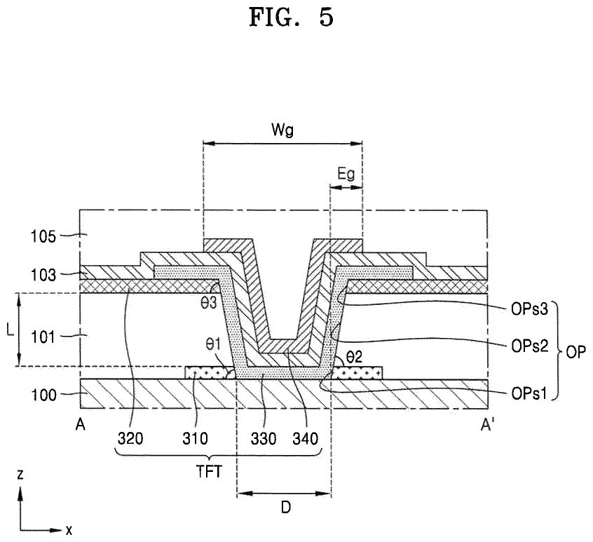

FIG. 4 is a schematic plan view of a thin film transistor according to an embodiment and FIG. 5 is a schematic cross-sectional view of the thin film transistor of FIG. 4 taken along line A-A′ according to an embodiment.

Referring to FIGS. 4 and 5, the display apparatus 10 (refer to FIG. 1) according to an embodiment may include a thin film transistor TFT disposed on the substrate 100. The thin film transistor TFT may be any one of the first transistor T1 and the second transistor T2 shown in FIG. 2A or may be any one of the first to seventh transistors T1 to T7 shown in FIG. 2B.

In an embodiment, the substrate 100 may include glass, metal, or polymer resin. In an embodiment, the substrate 100 may have flexible or bendable characteristics. In this embodiment, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate.

In some embodiments, the substrate 100 may include sapphire, gallium nitride (GaN), silicon carbide (SiC), silicon (Si), aluminum nitride (AlN), glass, and the like.

The thin film transistor TFT may be arranged on the substrate 100. The thin film transistor TFT may include a first electrode 310, a second electrode 320, a semiconductor layer 330, and a gate electrode 340. In an embodiment, the first electrode 310 may extend longitudinally in the second direction (e.g., the y direction) and the second electrode 320 may extend longitudinally in the first direction (e.g., the x direction) crossing the second direction (e.g., the y direction). The first electrode 310 may be a source electrode or a drain electrode of the thin film transistor TFT and the second electrode 320 may be a different electrode from the first electrode 310. For example, in an embodiment in which the first electrode 310 is a drain electrode, the second electrode 320 may be a source electrode.

In an embodiment, the first electrode 310 and the second electrode 320 may include Al, Pt, Pd, Ag, Mg, Au, Ni, Nd, Ir, Cr, Ca, Mo, Ti, W, and/or Cu. The first electrode 310 and the second electrode 320 may include a plurality of layers or a layer including the above materials.

FIG. 5 shows that the first electrode 310 is formed directly on an upper surface of the substrate 100 (e.g., in the z direction) such that the substrate 100 is in direct contact with the first electrode 310. However, embodiments of the present disclosure are not necessarily limited thereto. In some embodiments, at least one insulating layer, semiconductor layer, or conductive layer may be arranged between the substrate 100 and the first electrode 310 (e.g., in the z direction). For example, in an embodiment a silicon-based thin film transistor including a silicon-based semiconductor layer and a gate electrode on the silicon-based semiconductor layer may be arranged between the substrate 100 and the first electrode 310 (e.g., in the z direction).

A first insulating layer 101 may be arranged between the first electrode 310 and the second electrode 320 (e.g., in the z direction). In an embodiment, the first insulating layer 101 may include an inorganic insulating material such as silicon oxide, silicon nitride, and silicon oxynitride. The first electrode 310 and the second electrode 320 may be spaced apart from each other by a first distance L in the thickness direction (e.g., the z direction) by the first insulating layer 101.

In an embodiment, the first electrode 310 may have a first sub opening OPs1 defined therein in an area in which the first electrode 310 crosses the second electrode 320. The first insulating layer 101 may have a second sub opening OPs2 defined therein and overlapping the first sub opening OPs1. In an embodiment, the second electrode 320 may have a third sub opening OPs3 defined therein and overlapping the first sub opening OPs1 and the second sub opening OPs2. In an embodiment, the first sub opening OPs1, the second sub opening OPs2, and the third sub opening OPs3 may have a circular shape in a plan view. However, embodiments of the present disclosure are not necessarily limited thereto. For example, in some embodiments, the first sub opening OPs1, the second sub opening OPs2, and the third sub opening OPs3 may have a polygonal shape such as a rectangular shape or an atypical shape in a plan view.

The inner side of the first sub opening OPs1, the inner side of the second sub opening OPs2, and the inner side of the third sub opening OPs3 may be consecutive, thereby forming an opening OP penetrating through the first electrode 310, the first insulating layer 101 and the second electrode 320. For example, the inner side of the opening OP may be formed of an inner side of the first sub opening OPs1, an inner side of the second sub opening OPs2, and an inner side of the third sub opening OPs3 that are consecutively formed. The bottom surface of the opening OP may be the upper surface of the layer located below the first electrode 310. For example, as shown in FIG. 5, in an embodiment in which the first electrode 310 is directly disposed on the substrate 100, the bottom surface of the opening OP may be the upper surface of the substrate 100.

In an embodiment, a taper angle of the inner side of the first sub opening OPs1 may be a first angle θ1, a taper angle of the inner side of the second sub opening OPs2 may be a second angle θ2, and a taper angle of an inner side of the third sub opening OPs3 may be a third angle θ3. Here, the taper angle refers to an inclination of a corresponding surface with respect to the upper surface of the substrate 100. In an embodiment, the second angle θ2 may be less than or equal to 90°. In a comparative example, when the second angle is greater than or equal to 90°, the inner side of the second sub opening has an inversely tapered shape. In this comparative example, a defect may occur in a contact between the semiconductor layer and the first electrode, thereby greatly reducing the on-current of the thin film transistor. On the other hand, in the an embodiment of the present disclosure, the second angle θ2 is less than or equal to 90°, and thus, the semiconductor layer 330 may form a contact with the first electrode 310.

In an embodiment, the second angle θ2 may be different from the first angle θ1 and the third angle θ3. For example, in an embodiment the first angle θ1 and the third angle θ3 may be less than the second angle θ2. An inner side of the first sub opening OPs1 at which the first electrode 310 is in direct contact with the semiconductor layer 330 and an inner side of the third sub opening OPs3 at which the second electrode 320 is in direct contact with the semiconductor layer 330 may have inclined angles less than that of an inner side of the second sub opening OPs2. Therefore, the semiconductor layer 330 may form a strong contact with the first electrode 310 and the second electrode 320.

The semiconductor layer 330 may be disposed on the second electrode 320 to overlap the first sub opening OPs1, the second sub opening OPs2, and the third sub opening OPs3. The semiconductor layer 330 may include an oxide semiconductor material. For example, in an embodiment the semiconductor layer 330 may include an oxide of at least one material selected from a group consisting of indium (In), gallium (Ga), tin (Sn), zirconium (Zr), vanadium (V), hafnium (Hf), cadmium (Cd), germanium (Ge), chromium (Cr), titanium (Ti), aluminum (AI), cesium (Cs), cerium (Ce), and zinc (Zn). In an embodiment, the semiconductor layer 330 may be an InSnZnO (ITZO) semiconductor layer or an InGaZnO (IGZO) semiconductor layer.

The semiconductor layer 330 may extend from the upper surface of the second electrode 320 and may cover the inner sides of each of the first sub opening OPs1, the second sub opening OPs2, and the third sub opening OPs3. In an embodiment, the semiconductor layer 330 may extend to the bottom surface of the opening OP and have a U-shaped (e.g., a trench shape) cross section. The semiconductor layer 330 may be in direct contact with a side surface of the second electrode 320 and a side surface of the first electrode 310. The semiconductor layer 330 may be in direct contact with an upper surface of a layer below the first electrode 310 through the opening OP. For example, the semiconductor layer 330 may be in direct contact with an upper surface of the substrate 100 through the opening OP.

In an embodiment, as shown in FIG. 4, the semiconductor layer 330 may have a circular shape in a plan view. However, embodiments of the present disclosure are not necessarily limited thereto. For example, in some embodiments, in a plan view, the semiconductor layer 330 may have a polygonal shape such as a rectangle or an atypical shape. The center of the semiconductor layer 330 may overlap the opening OP.

In an embodiment, the semiconductor layer 330 extending along the inner side of the opening OP may act as a channel area of the thin film transistor TFT. A first distance L (e.g., length in the z direction) between the first electrode 310 and the second electrode 320, which are spaced apart by the first insulating layer 101, may determine a channel length of the thin film transistor TFT and a circumference of the opening OP may determine a channel width of the thin film transistor TFT. For example, the first distance L may be a distance between the upper surface of the first electrode 310 and the lower surface of the second electrode 320 (e.g., in the z direction).

A second insulating layer 103 may be disposed on (e.g., disposed directly thereon) the semiconductor layer 330. In an embodiment, the second insulating layer 103 may include an inorganic insulating material such as silicon oxide, silicon nitride, and silicon oxynitride. The second insulating layer 103 may be a gate insulating layer insulating the semiconductor layer 330 and the gate electrode 340 described below from each other. The second insulating layer 103 may be disposed on (e.g., disposed directly thereon) the upper surface of the semiconductor layer 330 and may have a U-shaped cross section within the opening OP. Thus, a groove recessed from the peripheral area may be formed on (e.g., defined on) the upper surface of the second insulating layer 103.

The gate electrode 340 may be disposed on the second insulating layer 103. In an embodiment, the gate electrode 340 may include Al, Pt, Pd, Ag, Mg, Au, Ni, Nd, Ir, Cr, Ca, Mo, Ti, W, and/or Cu. The gate electrode 340 may include a plurality of layers or a layer including the above materials.

In an embodiment, the gate electrode 340 may extend in the second direction (e.g., the y direction) to overlap the opening OP and may have a first width Wg in the first direction (e.g., the x direction). In an embodiment, the first width Wg of the gate electrode 340 may be greater than or equal to a diameter D of the opening OP. In an embodiment, the gate electrode 340 may cover an entirety of an inner side of the opening OP.

FIGS. 4 and 5 illustrate an embodiment in which the first width Wg of the gate electrode 340 is greater than the diameter D of the opening OP. Hereinafter, the diameter D of the opening OP may refer to a diameter of a bottom surface of the opening OP in the first direction (e.g., the x direction). Hereinafter, an area of the gate electrode 340 extending in the first direction (e.g., the x direction) from a boundary of the opening OP and overlapping the first electrode 310 may be referred to as an extension area. As the extension area is increased, a resistance of the gate electrode 340 may be decreased or a parasitic capacitance between the gate electrode 340 and the first electrode 310 and between the gate electrode 340 and the second electrode 320 may be increased. In an embodiment, a width Eg of a side of the extension area may be less than or equal to about 3 μm.

The gate electrode 340 may extend along the upper surface of the second insulating layer 103. For example, the gate electrode 340 may extend along the inner side and the bottom surface of the groove formed by (e.g., defined on) the upper surface of the second insulating layer 103. In an embodiment, the gate electrode 340 may have a U-shaped cross section in the opening OP corresponding to the shape of the semiconductor layer 330 and the second insulating layer 103.

As a comparative example, if the first electrode of the thin film transistor does not include the first sub opening, the gate electrode may overlap the first electrode at the inner side of the opening. In this comparative example, since, inside the opening, only the semiconductor layer and the second insulating layer are arranged between the gate electrode and the first electrode, the gate electrode and the first electrode may be adjacent to each other in a thickness direction. Thus, the parasitic capacitance between the gate electrode and the first electrode may reduce the on-current of the thin film transistor.

On the other hand, in an embodiment of the present disclosure, since the first electrode 310 includes a first sub opening OPs1 penetrating through the first electrode 310, inside the opening OP, the gate electrode 340 may not overlap the first electrode 310. Therefore, the parasitic capacitance between the gate electrode 340 and the first electrode 310 may be greatly reduced and an on-current of the thin film transistor TFT may be increased, and thus, a charge rate margin of the pixel P (refer to FIGS. 2A and 2B) may be obtained.

The third insulating layer 105 may be disposed on (e.g., disposed directly thereon) the gate electrode 340. In an embodiment, the third insulating layer 105 may include an inorganic insulating material such as silicon oxide, silicon nitride, and silicon oxynitride. The organic light-emitting diode OLED (refer to FIG. 3) may be disposed on the third insulating layer 105.

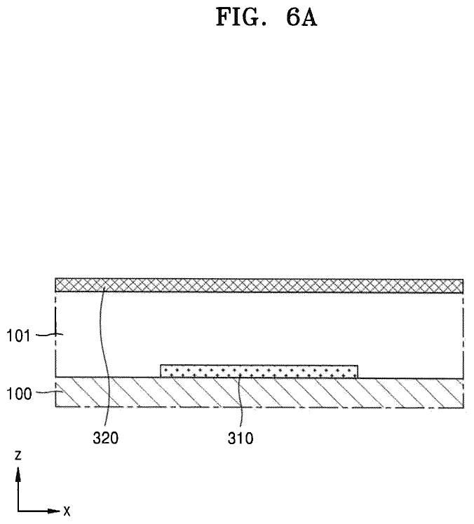

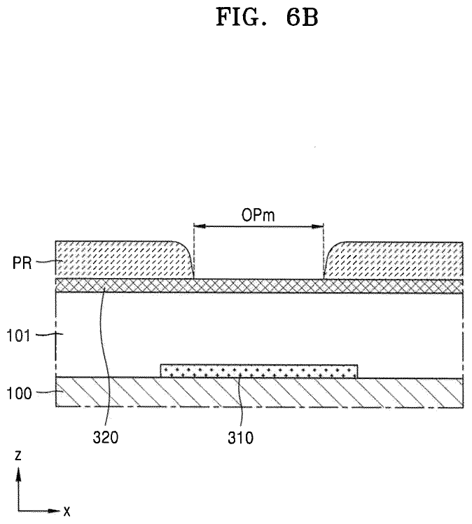

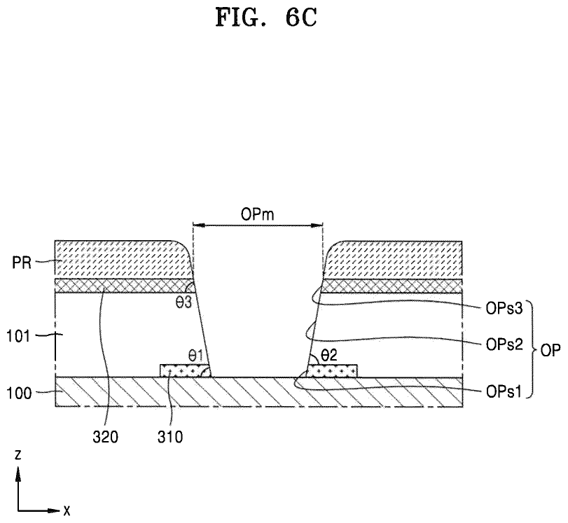

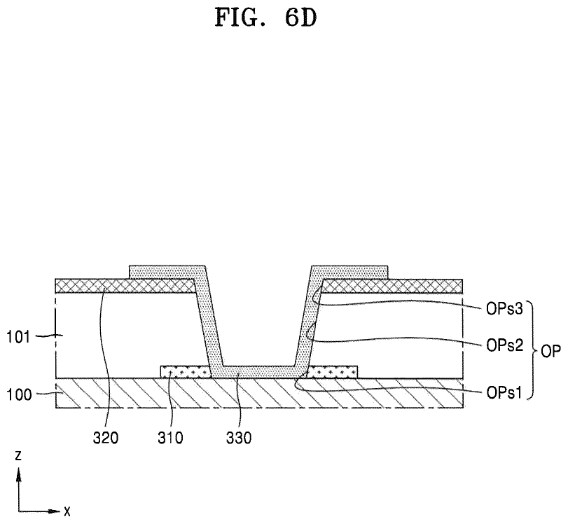

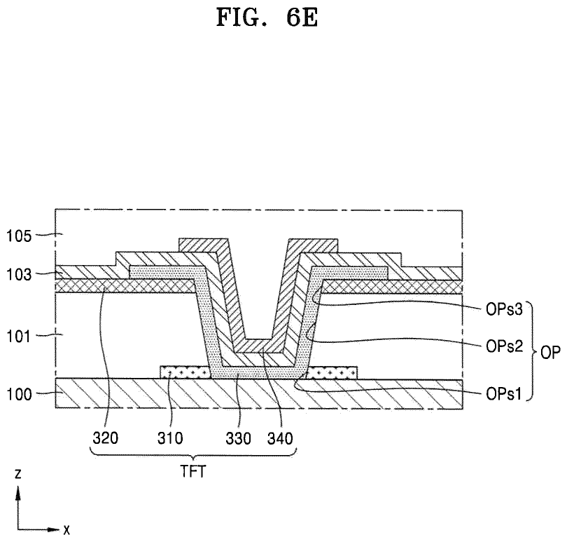

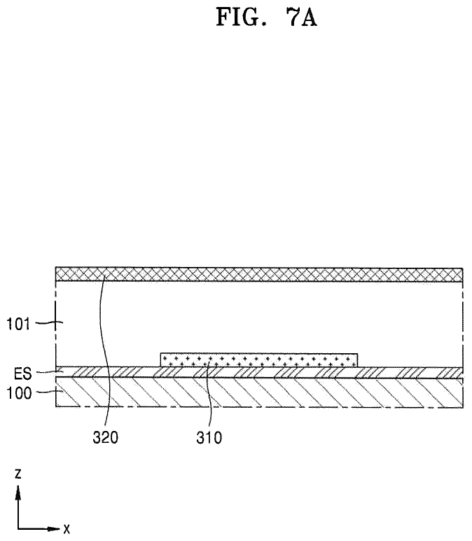

FIGS. 6A to 6E are cross-sectional views schematically illustrating some stages of a method of manufacturing a thin film transistor according to embodiments of the present disclosure.

Referring to FIG. 6A, after forming the first electrode 310 on the substrate 100 (e.g., formed directly thereon in the z direction) and forming the first insulating layer 101 on (e.g., directly thereon) the first electrode 310, the second electrode 320 may be formed on the first insulating layer 101 (e.g., formed directly thereon in the z direction).

In an embodiment, the first electrode 310 may extend longitudinally in the second direction (e.g., the y direction) and the second electrode 320 may extend longitudinally in the first direction (e.g., the x direction) crossing the second direction (e.g., the y direction). The first electrode 310 may be a source electrode or a drain electrode of the thin film transistor TFT and the second electrode 320 may be a different electrode from the first electrode 310.

The first electrode 310 and the second electrode 320 may be separated from each other in the thickness direction (e.g., the z direction) by the first insulating layer 101, and the distance between the first electrode 310 and the second electrode 320 may determine the channel length of the thin film transistor. For example, the channel length of the thin film transistor may be determined by a stack thickness of the first insulating layer 101.

FIGS. 6A to 6E show that the first electrode 310 is formed directly on the upper surface of the substrate 100. However, embodiments of the present disclosure are not necessarily limited thereto. In some embodiments, at least one insulating layer may be arranged between the substrate 100 and the first electrode 310. As described above, in an embodiment a silicon-based thin film transistor including a silicon-based semiconductor layer and a gate electrode on the silicon-based semiconductor layer may be arranged between the substrate 100 and the first electrode 310. In an embodiment, the first electrode 310 may be formed on the upper surface of the insulating layer covering the silicon-based thin film transistor.

Referring to FIG. 6B, a mask opening OPm overlapping the second electrode 320 and the first electrode 310 (e.g., in the z direction) may be formed by stacking a photoresist layer PR on the second electrode 320 and removing a portion of the photoresist layer PR. In an embodiment, in a plan view, the mask opening OPm may overlap an area in which the second electrode 320 crosses the first electrode 310 (for example, a center of the area) and may have a circular shape.

Referring to FIG. 6C, by using the photoresist layer PR as a mask, an opening OP penetrating the second electrode 320, the first insulating layer 101, and the first electrode 310 may be formed. For example, in an embodiment the third sub opening OPs3 may be formed by removing a portion of the second electrode 320 exposed through the mask opening OPm, the second sub opening OPs2 may be formed by removing a portion of the first insulating layer 101 exposed through the third sub opening OPs3, and the first sub opening OPs1 may be formed by removing a portion of the first electrode 310 exposed through the second sub opening OPs2. In an embodiment, the third sub opening OPs3, the second sub opening OPs2, and the first sub opening OPs1 may be consecutively formed by an etching process. The inner side of the third sub opening OPs3, the inner side of the second sub opening OPs2, and the inner side of the first sub opening OPs1 may be consecutively formed. For example, the etching process may be a dry etching process.

The opening OP may be formed to have a circular shape in a plan view. The opening OP may be deep enough to expose the upper surface of a layer below the first electrode 310. For example, in an embodiment in which the first electrode 310 is formed directly on the substrate 100 as shown in FIG. 6C, the bottom surface of the opening OP may be the upper surface of the substrate 100.

The taper angle of the inner side of the first sub opening OPs1 may be the first angle θ1, the taper angle of the inner side of the second sub opening OPs2 may be the second angle θ2, and the taper angle of the inner side of the third sub opening OPs3 may be the third angle θ3. In an embodiment, the second angle θ2 may be less than or equal to 90°. The second angle θ2 may be equal to or different from the first angle θ1 and the third angle θ3. For example, the first angle θ1 and the third angle θ3 may be less than the second angle θ2 such that the first electrode 310 forms a direct contact with the semiconductor layer 330 and the second electrode 320 forms a direct contact with the semiconductor layer 330.

Subsequently, the photoresist layer PR may be removed.

Referring to FIG. 6D, the semiconductor layer 330 may be formed on the second electrode 320 to overlap the opening OP. In an embodiment, the semiconductor layer 330 may be formed by using known methods such as sputtering, chemical vapor deposition, and atomic layer deposition. The semiconductor layer 330 may have a circular shape in a plan view. However, embodiments of the present disclosure are not necessarily limited thereto. For example, in some embodiments, in a plan view, the semiconductor layer 330 may have a polygonal shape such as a rectangle or an atypical shape. The center of the semiconductor layer 330 may overlap the opening OP.

The semiconductor layer 330 may be formed to cover the inner side of the opening OP. For example, the semiconductor layer 330 may cover the inner side of the third sub opening OPs3, the inner side of the second sub opening OPs2, and the inner side of the first sub opening OPs1. The semiconductor layer 330 may be in direct contact with a side surface of the second electrode 320 and a side surface of the first electrode 310. The semiconductor layer 330 may extend to the bottom surface of the opening OP from the upper surface of the second electrode 320 and may have a U-shaped (e.g., a trench shape) cross section in the opening OP. The semiconductor layer 330 may be in direct contact with an upper surface of a layer below the first electrode 310 through the opening OP.

A portion of the semiconductor layer 330 arranged along the inner side of the opening OP and between the first electrode 310 and the second electrode 320 may act as a channel area of the thin film transistor TFT. Therefore, the distance between the first electrode 310 and the second electrode 320, which are separated from each other by the first insulating layer 101 in the thickness direction (e.g., the z direction), may determine the channel length of the thin film transistor TFT and the circumference of the opening OP may determine the channel width of the thin film transistor TFT.

Referring to FIG. 6E, the second insulating layer 103 may be formed on (e.g., formed directly thereon) the semiconductor layer 330 and the gate electrode 340 may be formed on (e.g., formed directly thereon) the second insulating layer 103. In an embodiment, the gate electrode 340 may be formed by known methods such as sputtering, chemical vapor deposition, and atomic layer deposition.

The second insulating layer 103 may be formed along the upper surface of the semiconductor layer 330 and may have a U-shaped cross section in the opening OP. Thus, a groove recessed from the peripheral area may be formed on the upper surface of the second insulating layer 103.

In an embodiment, the gate electrode 340 may extend longitudinally in the second direction (e.g., the y direction) to overlap the opening OP. The width of the gate electrode 340 in the first direction (e.g., the x direction) may be greater than or equal to the diameter of the opening OP such that the opening OP is covered by the gate electrode 340 in a plan view. The gate electrode 340 may extend along the upper surface of the second insulating layer 103. For example, the gate electrode 340 may extend along the inner side and the bottom surface of the groove formed by the upper surface of the second insulating layer 103. The gate electrode 340 may have a U-shaped cross section in the opening OP corresponding to the shape of the semiconductor layer 330 and the second insulating layer 103.

Since the first electrode 310 includes a first sub opening OPs1 penetrating through the first electrode 310, inside the opening OP, the gate electrode 340 may not overlap the first electrode 310.

The third insulating layer 105 may be formed on (e.g., formed directly thereon) the gate electrode 340.

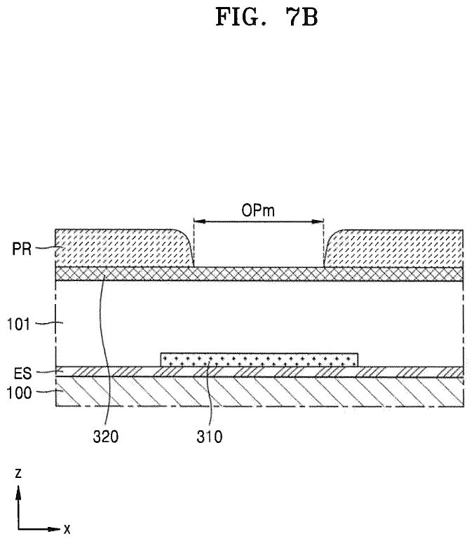

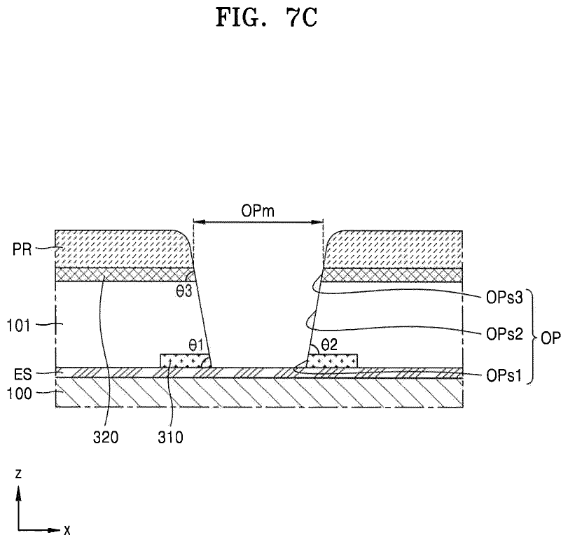

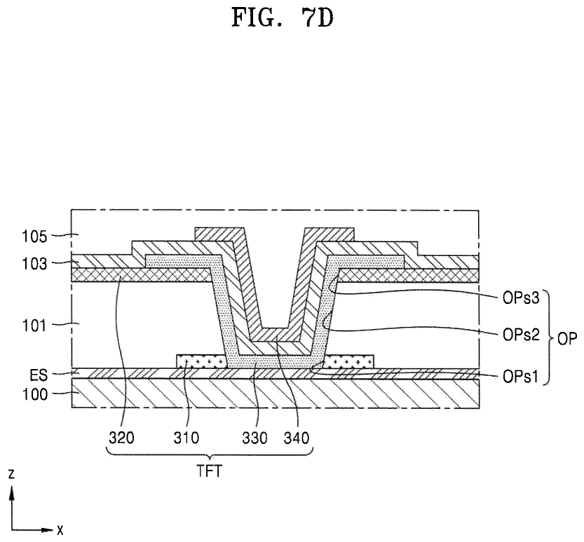

FIGS. 7A to 7D are cross-sectional views schematically illustrating some stages of the method of manufacturing the thin film transistor according to embodiments of the present disclosure.

Referring to FIG. 7A, after an etch stopper ES is formed on the substrate 100 (e.g., formed directly thereon in the z direction), the first electrode 310 may be formed on the etch stopper ES (e.g., formed directly thereon in the z direction), and after the first insulating layer 101 is formed on the first electrode 310, the second electrode 320 may be formed on the first insulating layer 101 (e.g., formed directly thereon in the z direction).

The etch stopper ES may include a material with a different etching speed from that of the first electrode 310. In an embodiment, the etch stopper ES may include silicon oxide, silicon nitride, silicon oxynitride, and the like. In some embodiments, the etch stopper ES may include at least one oxide or nitride of indium (In), gallium (Ga), zinc (Zn), tin (Sn), aluminum (AI), magnesium (Mg), titanium (Ti), hafnium (Hf), yttrium (Y), and zirconium (Zr).

In an embodiment shown in FIG. 7A, the etch stopper ES may be formed on the entire surface of the substrate 100. However, embodiments of the present disclosure are not necessarily limited thereto. In an embodiment, the etch stopper ES may be patterned to only overlap the area in which the first electrode 310 crosses the second electrode 320. In this embodiment, the etch stopper ES may be an island type in a plan view.

In embodiments shown in FIGS. 7A to 7D the etch stopper ES is formed directly on the upper surface of the substrate 100. However, embodiments of the present disclosure are not necessarily limited thereto. For example, in an embodiment at least one insulating layer may be arranged between the substrate 100 and the etch stopper ES (e.g., in the z direction). In an embodiment, a silicon-based thin film transistor may be arranged between the substrate 100 and the etch stopper ES (e.g., in the z direction). In this embodiment, the etch stopper ES may be formed on the upper surface of the insulating layer covering the silicon-based thin film transistor.

Referring to FIG. 7B, the mask opening OPm overlapping the second electrode 320 and the first electrode 310 may be formed by stacking a photoresist layer PR on the second electrode 320 (e.g., directly thereon in the z direction) and removing a portion of the photoresist layer PR. In a plan view, the mask opening OPm may overlap a center of the area in which the second electrode 320 crosses the first electrode 310 and may have a circular shape.

Referring to FIG. 7C, by using the photoresist layer PR as a mask, the opening OP penetrating the second electrode 320, the first insulating layer 101, and the first electrode 310 may be formed. For example, in an embodiment the third sub opening OPs3 may be formed by removing a portion of the second electrode 320 exposed through the mask opening OPm, the second sub opening OPs2 may be formed by removing a portion of the first insulating layer 101 exposed through the third sub opening OPs3, and the first sub opening OPs1 may be formed by removing a portion of the first electrode 310 exposed through the second sub opening OPs2. In an embodiment, the third sub opening OPs3, the second sub opening OPs2, and the first sub opening OPs1 may be consecutively formed by an etching process. The inner side of the third sub opening OPs3, the inner side of the second sub opening OPs2, and the inner side of the first sub opening OPs1 may be consecutively formed.

The opening OP may be formed deep enough to expose the upper surface of the etch stopper ES. Since the etch stopper ES has an etching speed lower than the etching speed of the first electrode 310, it is possible to prevent damage to the layers below the etch stopper ES when the opening OP is formed. In addition, the depth dispersion of the opening OP may be reduced.

A taper angle of the inner side of the first sub opening OPs1 may have a first angle θ1, the taper angle of the inner side of the second sub opening OPs2 may have a second angle θ2, and a taper angle of an inner side of the third sub opening OPs3 may have a third angle θ3. In an embodiment, the second angle θ2 may be less than or equal to 90°. The second angle θ2 may be equal to or different from the first angle θ1 and the third angle θ3. In an embodiment, the first angle θ1 and the third angle θ3 may be less than the second angle θ2 such that the first electrode 310 sufficiently forms a contact with the semiconductor layer 330 and the second electrode 320 sufficiently forms a contact with the semiconductor layer 330.

Subsequently, the photoresist layer PR may be removed.

Referring to FIG. 7D, the semiconductor layer 330 may be formed on (e.g., formed directly thereon) the second electrode 320 to overlap the opening OP, the second insulating layer 103 may be formed on (e.g., formed directly thereon) the semiconductor layer 330, and the gate electrode 340 may be formed on (e.g., formed directly thereon) the second insulating layer 103.

In an embodiment, the semiconductor layer 330 may have a circular shape in a plan view. However, embodiments of the present disclosure are not necessarily limited thereto. For example, in some embodiments, in a plan view, the semiconductor layer 330 may have a polygonal shape such as a rectangle or an atypical shape. The center of the semiconductor layer 330 may overlap the opening OP.

The semiconductor layer 330 may be formed to cover the inner side of the opening OP. For example, the semiconductor layer 330 may cover the inner side of the first sub opening OPs1, the inner side of the second sub opening OPs2, and the inner side of the third sub opening OPs3. The semiconductor layer 330 may extend to the bottom surface of the opening OP from the upper surface of the second electrode 320 and may have a U-shaped (e.g., a trench shape) cross section in the opening OP. In an embodiment, the semiconductor layer 330 may be in direct contact with an upper surface of the etch stopper ES through the opening OP. A portion of the semiconductor layer 330 extending along the inner side of the opening OP and between the first electrode 310 and the second electrode 320 may act as a channel area of the thin film transistor TFT.

The gate electrode 340 may extend longitudinally in the second direction (e.g., the y direction) to overlap the opening OP. The width of the gate electrode 340 in the first direction (e.g., the x direction) may be greater than or equal to the diameter of the opening OP such that the opening OP is covered by the gate electrode 340 in a plan view. The gate electrode 340 may extend along the upper surface of the second insulating layer 103.

Since the first electrode 310 includes a first sub opening OPs1 penetrating through the first electrode 310, inside the opening OP, the gate electrode 340 may not overlap the first electrode 310 (e.g., in a plan view).

In an embodiment, the third insulating layer 105 may then be formed on (e.g., formed directly thereon) the gate electrode 340.

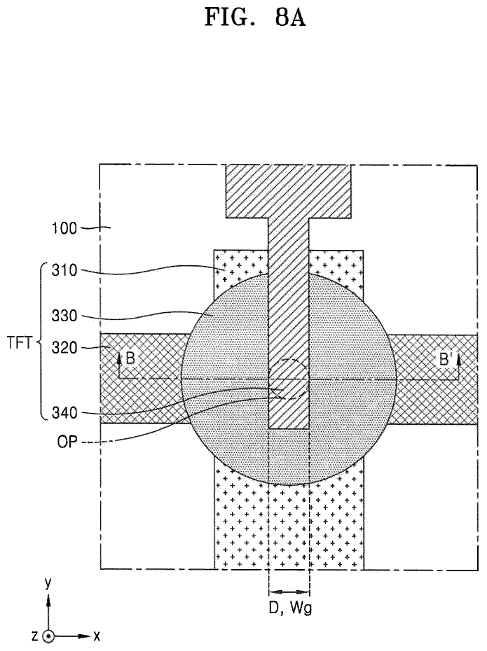

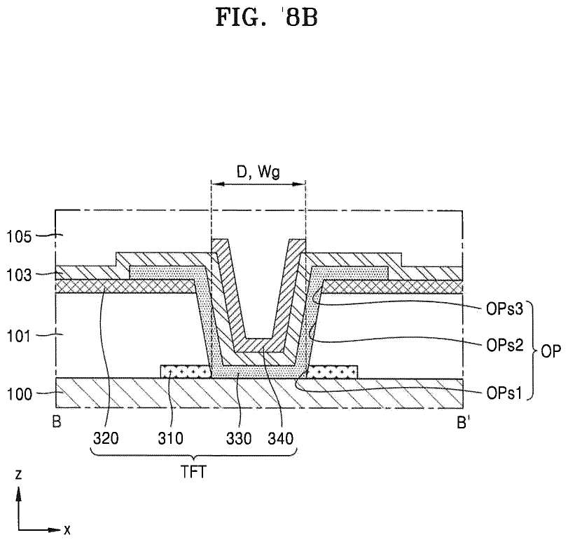

FIG. 8A is a schematic plan view of a thin film transistor according to an embodiment and FIG. 8B is a schematic cross-sectional view of the thin film transistor shown in FIG. 8A taken along line B-B′ according to an embodiment.

FIGS. 8A and 8B may be similar with FIGS. 4 and 5, except the first width Wg of the gate electrode 340 in the first direction (e.g., the x direction) is equal to the diameter D of the opening OP. Hereinafter, identical or similar elements may be omitted and differences are mainly described for economy of description.

Referring to FIGS. 8A and 8B, the gate electrode 340 may overlap the opening OP and extend longitudinally in the second direction (e.g., the y direction). The gate electrode 340 may have the first width Wg in the first direction (e.g., the x direction). In an embodiment, the first width Wg may be the same as the diameter D of the opening OP.

In a comparative example, when the first width of the gate electrode is less than the diameter of the opening, the gate electrode may not fully cover the inner side of the opening, thereby forming only a portion of the channel area of the thin film transistor. In a comparative example in which the first width of the gate electrode is excessively greater than the diameter of the opening, the extension area of the gate electrode in which the gate electrode overlaps the first electrode may be increased, thereby increasing the parasitic capacitance between the gate electrode and the first electrode and between the gate electrode and the second electrode.

In an embodiment, since the gate electrode 340 has the same width, such as the first width Wg, as the diameter D of the opening OP, the gate electrode 340 may cover an entirety of the inner side of the opening OP. Thus, the channel area of the thin film transistor TFT may be formed on the inner side of the opening OP along the circumference of the opening OP. In addition, by reducing or minimizing the area in which the gate electrode 340 overlaps the first electrode 310 and the area in which the gate electrode 340 overlaps the second electrode 320, the parasitic capacitance between the gate electrode 340 and the first electrode 310 and the parasitic capacitance between the gate electrode 340 and the second electrode 320 may be reduced. Thus, the thin film transistor TFT according to an embodiment may have an increased on-current.

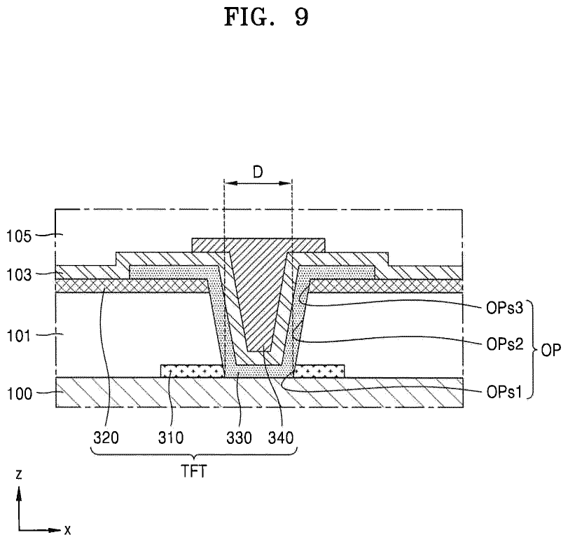

FIG. 9 is a schematic cross-sectional view of the thin film transistor according to an embodiment.

FIG. 9 is similar with FIG. 4 but is different from FIG. 4 in that the groove formed on the upper surface of the second insulating layer 103 is filled by the gate electrode 340. Hereinafter, identical or similar elements may be omitted and differences are mainly described for economy of description.

Referring to FIG. 9, the gate electrode 340 may overlap the opening OP and extend longitudinally in the second direction (e.g., the y direction). The gate electrode 340 may have a first width in the first direction (e.g., the x direction) and the first width may be greater than or equal to the diameter D of the opening OP.

The semiconductor layer 330 may extend from the upper surface of the second electrode 320 and may cover the inner sides of each of the first sub opening OPs1, the second sub opening OPs2, and the third sub opening OPs3. The semiconductor layer 330 may extend to the bottom surface of the opening OP and have a U-shaped (e.g., a trench shape) cross section in the opening OP.

The second insulating layer 103 may be disposed on (e.g., disposed directly thereon) the upper surface of the semiconductor layer 330 and may have a U-shaped cross section in the opening OP. Thus, a groove recessed from the peripheral area may be formed on the upper surface of the second insulating layer 103.

In an embodiment, the diameter D of the opening OP may have a value of several micrometers (μm) or less. For example, in an embodiment the diameter D of the opening OP may be less than or equal to about 1 μm. In this embodiment, the gate electrode 340 may be formed thickly enough to fill the whole opening OP. For example, the gate electrode 340 may extend along the inner side and the bottom surface of the groove formed by the upper surface of the second insulating layer 103 and may fill the opening OP. The gate electrode 340 may have a T-shape in a plan view.

The display apparatus according to an embodiment of the present disclosure may reduce the two-dimensional area of the thin film transistor TFT, thereby integrating the pixels at a high density to display a high-resolution image.

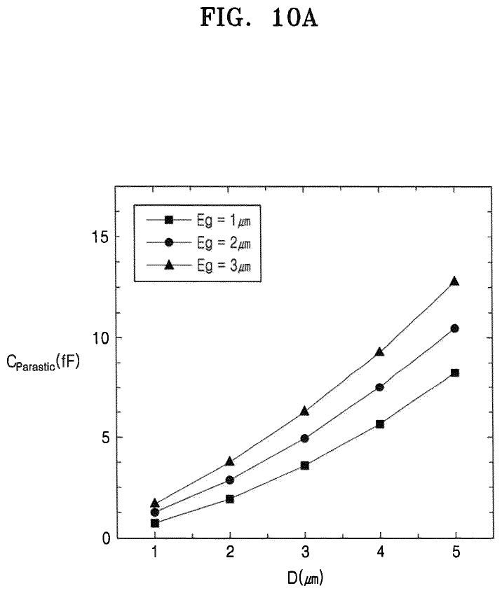

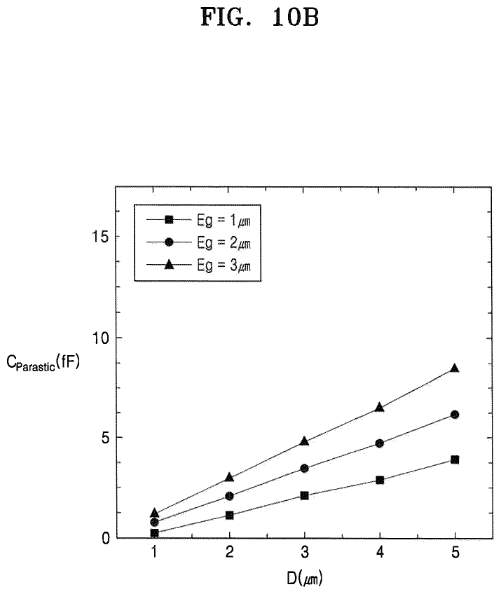

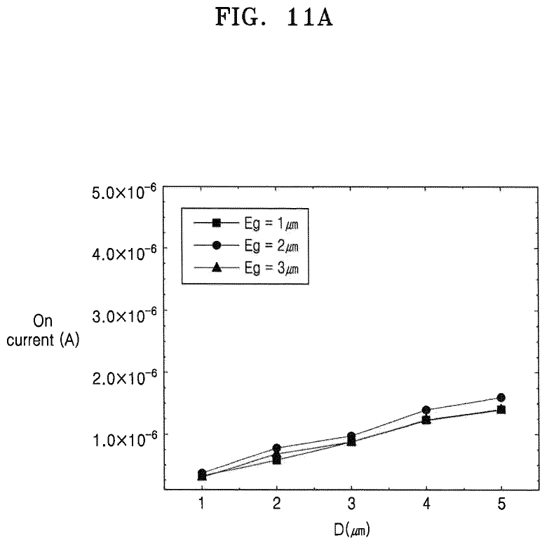

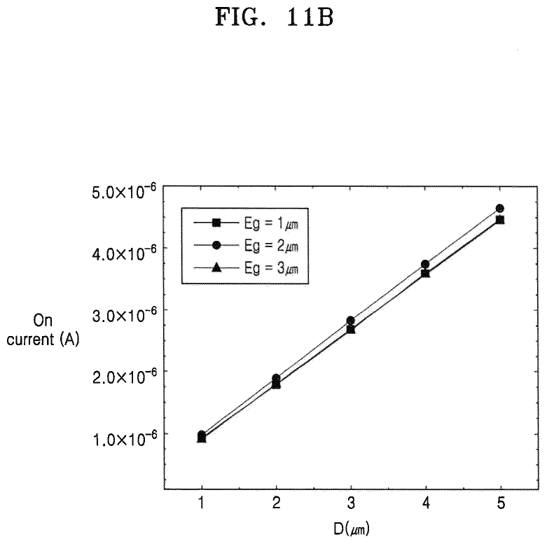

FIG. 10A is a graph showing a parasitic capacitance between the gate electrode and the first electrode of the thin film transistor of the comparative example, FIG. 10B is a graph showing a parasitic capacitance between the gate electrode and the first electrode of the thin film transistor according to an embodiment of the present disclosure, FIG. 11A is a graph showing the on-current of the thin film transistor of the comparative example, and FIG. 11B is a graph showing the on-current of the thin film transistor according to an embodiment of the present disclosure.

Here, the thin film transistor of an embodiment of the present disclosure has the same structure as the thin film transistor described with reference to FIG. 4. It is assumed that the thickness of the first electrode 310 and the second electrode 320 of the thin film transistor TFT is 200 nm, the thickness of the first insulating layer 101 is 500 nm, the thickness of the semiconductor layer 330 is 30 nm, the thickness of the second insulating layer 103 is 140 nm, and the thickness of the gate electrode 340 is 300 nm. The semiconductor layer 330 may be an IGZO layer and the first insulating layer 101 and the second insulating layer 103 may be a silicon oxide layer.

The thin film transistor of the comparative example has the same structure as the thin film transistor according to an embodiment of the present disclosure, but is different from the thin film transistor of an embodiment of the present disclosure in that the comparative example does not include the feature wherein the first sub opening is formed in the first electrode. Thus, the bottom surface of the opening in the comparative example is the upper surface of the first electrode. The semiconductor layer of the thin film transistor of the comparative example is in direct contact with the upper surface of the first electrode through the opening.

In FIGS. 10A to 11B, D refers to the diameter of the opening and Eg represents the width of the extension area, which is where the gate electrode overlaps the first electrode.

Referring to FIGS. 10A and 10B, as the diameter D of the opening of the thin film transistor and the width Eg of the extension area are increased, the parasitic capacitance C_{Parastic} of the thin film transistor may be increased. In this case, as shown in FIG. 10A, the parasitic capacitance C_{Parastic} of the thin film transistor of the comparative example may be about 12 fF or more when the diameter D of the opening is 5 μm and the width Eg of the extension area is 3 μm. On the other hand, as shown in FIG. 10B, the parasitic capacitance C_{Parastic} of the thin film transistor of an embodiment of the present disclosure may be about 9 fF or less when the diameter D of the opening is 5 μm and the width Eg of the extension area is 3 μm. When the diameter D of the opening and the width Eg of the extension area are the same, respectively, the parasitic capacitance C_{Parastic} of the thin film transistor of the present embodiment may be less than the parasitic capacitance C_{Parastic} of the thin film transistor of the comparative example.

Referring to FIGS. 11A and 11B, as the diameter D of the opening of the thin film transistor and the width Eg of the extension area are increased, the on-current of the thin film transistor may be increased. In this case, as shown in FIG. 11A, the on-current of the thin film transistor of the comparative example may have a value of less than 2.0×10⁻⁶ A. On the other hand, as shown in FIG. 11B, the on-current of the thin film transistor of the present embodiment may have a value greater than 4.0×10⁻⁶ A when the diameter D of the opening is 5 μm. It is shown that, when the diameter D of the opening and the width Eg of the extension area are the same, respectively, the parasitic capacitance of the thin film transistor of the present embodiment may be less than the parasitic capacitance of the thin film transistor of the comparative example.

According to an embodiment of the present disclosure, the thin film transistor may have a channel area extending in the thickness direction, thereby significantly reducing the two-dimensional area of the thin film transistor (e.g., in a plan view). In addition, since the opening is formed to penetrate through the second electrode, the first insulating layer, and the first electrode, the parasitic capacitance between the gate electrode and the first electrode may be reduced and the on-current of the thin film transistor may be increased. Thus, the display apparatus including the thin film transistor according to an embodiment of the present disclosure may display a high-resolution image while operating at low power.

According to an embodiment of the present disclosure, a thin film transistor of which the parasitic capacitance between the gate electrode and the source-drain electrode is reduced and the display apparatus including the same may be implemented. However, the scope of embodiments of the present disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more non-limiting embodiments have been described with reference to the figures, it will be understood by those of ordinary skill in the art that various changes in form and details may be made therein without departing from the spirit and scope of the present disclosure.

What is claimed is:

1. A thin film transistor comprising:
a substrate;
a first electrode disposed on the substrate, the first electrode having a first opening defined therein;
a first insulating layer disposed on the first electrode, the first insulating layer having a second opening defined therein, the second opening overlapping the first opening;
a second electrode disposed on the first insulating layer, the second electrode having a third opening defined therein, the third opening overlapping the first opening;
a semiconductor layer disposed on the second electrode and overlapping the first opening, the second opening, and the third opening;
a second insulating layer disposed on the semiconductor layer; and
a gate electrode disposed on the second insulating layer.

2. The thin film transistor of claim 1, wherein the semiconductor layer covers inner sides of each of the first opening, the second opening, and the third opening.

3. The thin film transistor of claim 1, wherein the first opening, the second opening, and the third opening have a circular shape in a plan view.

4. The thin film transistor of claim 3, wherein the semiconductor layer has a circular shape in a plan view.

5. The thin film transistor of claim 1, wherein a width of the gate electrode in a first direction is greater than or equal to a diameter of the first opening in the first direction.

6. The thin film transistor of claim 1, wherein:
a groove is defined on an upper surface of the second insulating layer; and
the gate electrode fills the groove.

7. The thin film transistor of claim 1, wherein a taper angle of an inner side of the second opening is less than or equal to 90°.

8. The thin film transistor of claim 7, wherein:
a taper angle of an inner side of the first opening is a first angle;
the taper angle of the inner side of the second opening is a second angle;
a taper angle of an inner side of the third opening is a third angle; and
the first angle and the third angle are less than the second angle.

9. The thin film transistor of claim 1, further comprising an etch stopper arranged between the substrate and the first electrode, wherein a bottom surface of the first opening exposes an upper surface of the etch stopper.

10. The thin film transistor of claim 1, wherein the semiconductor layer comprises an oxide semiconductor material.

11. A display apparatus comprising:
a substrate;
a thin film transistor disposed on the substrate; and
a light-emitting diode electrically connected to the thin film transistor, wherein
the thin film transistor comprises:
a first electrode disposed on the substrate;
a first insulating layer disposed on the first electrode;
a second electrode disposed on the first insulating layer;
an opening penetrating through the first electrode, the first insulating layer and the second electrode;
a semiconductor layer disposed in the opening and directly contacting sides of the first electrode, the first insulating layer and the second electrode exposed by the opening; and
a gate electrode disposed on the semiconductor layer in the opening,
wherein the semiconductor layer disposed in the opening extends vertically between the first electrode and the second electrode.

12. A method of manufacturing a thin film transistor, the method comprising:
forming a first electrode on a substrate;
forming a first insulating layer on the first electrode;
forming a second electrode on the first insulating layer;
forming an opening penetrating through the second electrode, the first insulating layer, and the first electrode;
forming a semiconductor layer on the second electrode to overlap the opening;
forming a second insulating layer on the semiconductor layer; and
forming a gate electrode on the second insulating layer.

13. The method of claim 12, wherein the semiconductor layer covers an inner side of the opening.

14. The method of claim 12, wherein the opening has a circular shape in a plan view.

15. The method of claim 12, wherein a width of the gate electrode in a first direction is greater than or equal to a diameter of a bottom surface of the opening in the first direction.

16. The method of claim 12, wherein:
a groove is defined on an upper surface of the second insulating layer; and
the gate electrode fills the groove.

17. The method of claim 12, wherein:
the opening has a first opening defined in the first electrode, a second opening defined in the first insulating layer, and a third opening defined in the second electrode, wherein the first opening, the second opening, and the third opening overlap each other, and
a taper angle of an inner side of the second opening is less than or equal to 90°.

18. The method of claim 17, wherein:
a taper angle of an inner side of the first opening is a first angle;
the taper angle of the inner side of the second opening is a second angle;
a taper angle of an inner side of the third opening is a third angle; and
the first angle and the third angle are less than the second angle.

19. The method of claim 12, further comprising forming an etch stopper on the substrate before the forming of the first electrode.

20. The method of claim 19, wherein the opening exposes an upper surface of the etch stopper.
